(19) United States
(12) Patent Application Publication
(10) Pub. No.: US 2006/0073613 A1
(43) Pub. Date: Apr. 6, 2006

(54) Ferroelectric memory cells and methods for fabricating ferroelectric memory cells and ferroelectric capacitors thereof

(76) Inventors: Sanjeev Aggarwal, Plano, TX (US); K. R. Udayakumar, Dallas, TX (US); James Scott Martin, Garland, TX (US)

Correspondence Address: TEXAS INSTRUMENTS INCORPORATED, P O BOX 655474, M/S 3999, DALLAS, TX, 75265, US

(21) Appl. No.: 10/952,987

(22) Filed: Sep. 29, 2004

(51) Int. Cl. H01L 21/00; H01L 21/20; H01L 21/8242

(52) U.S. Cl. 438/3; 438/381; 438/240; 438/239

(57) ABSTRACT

Methods (100) are provided for fabricating a ferroelectric capacitor in a semiconductor device wafer, comprising forming (118) a lower electrode, depositing (126) PZT ferroelectric material on the lower electrode at a temperature below 450 degrees C., and forming (128) an upper electrode on the PZT. Methods are also provided for fabricating a ferroelectric memory cell in a semiconductor device wafer, comprising forming (106) a transistor in the wafer, forming (108) a nickel silicide structure on the gate or a source/drain of the transistor, forming (110) a dielectric over the transistor, forming (112) a conductive contact extending through the dielectric to the silicide structure, forming (114, 116, 118, 120) a lower electrode on at least a portion of the conductive contact, forming (126) PZT ferroelectric material above and in contact with the lower electrode at a temperature below 450 degrees C., forming (128, 132) an upper electrode above and in contact with the PZT, and patterning (134) the upper electrode, the PZT, and the lower electrode to form a patterned ferroelectric capacitor.

### FIELD OF INVENTION

The present invention relates generally to semiconductor devices and more particularly ferroelectric memory cells and methods for fabricating ferroelectric memory cells and ferroelectric capacitors.

### BACKGROUND OF THE INVENTION

Memory systems are used for storage of data, program code, and/or other information in many electronic products, such as personal computer systems, embedded processor-based systems, video image processing circuits, portable phones, and the like. Memory may be provided in the form of a dedicated memory integrated circuit (IC) or may be embedded (included) within a processor or other IC as on-chip memory. Ferroelectric memory, sometimes referred to as “FRAM” or “FERAM”, is a non-volatile form of memory commonly organized in single-transistor, single-capacitor (1T1C) or two-transistor, two-capacitor (2T2C) cell configurations, in which each memory cell includes one or more access transistors and cell capacitors formed using ferroelectric dielectric material. The non-volatility of an FERAM memory cell is the result of the bi-stable characteristic of the ferroelectric dielectric material in the cell capacitor(s), wherein the ferroelectric material has multiple electrically distinguishable stable states.

Ferroelectric memory is often fabricated in stand-alone memory integrated circuits (ICs) and/or in logic circuits having on-board non-volatile memory (e.g., microprocessors, DSPs, communications chips, etc.). The ferroelectric memory cells are typically organized in an array architecture, such as folded-bitline, open-bitline, etc., wherein the individual cells are selected by plateline and wordline signals from address decoder circuitry, with the data being read from or written to the cells along bitlines using latch or sense amp circuits. In a typical 1T1C memory cell, a ferroelectric capacitor is coupled between a plateline signal and a source/drain of a MOS cell transistor, the other source/drain is connected to a bitline, and the transistor gate is connected to a wordline control signal to selectively couple the capacitor with the bitline during read and write operations.

The ferroelectric memory arrays are typically constructed in a device wafer along with CMOS logic circuits, wherein the cell transistors are formed concurrently with logic transistors in the device, and the ferroelectric capacitors are constructed in a capacitor layer above the wafer substrate. For example, the construction of the ferroelectric cell capacitors may be integrated into a CMOS fabrication process flow after transistor formation (e.g., after ‘front-end’ processing), and before the metalization or interconnection processing (e.g., before ‘back-end’ processing). In a typical integration of ferroelectric capacitors in a CMOS process flow, transistors are formed on/in a semiconductor body, and a pre-metal dielectric (PMD) layer is constructed over the transistors, including tungsten contacts extending through the PMD level dielectric to the gate and source/drain terminals of the transistors. Ferroelectric capacitors are then constructed in a first inter-level dielectric layer (e.g., ILD0) above the PMD level, where one of the cell capacitor electrodes is connected to a cell transistor terminal (e.g., typically a source/drain) through one of the tungsten PMD contacts, wherein interconnection of the other capacitor electrode and the remaining transistor terminals with other components (e.g., signal routing) is provided in one or more metalization layers or levels above the ILD0 level.

In the construction of the ferroelectric cell capacitors in the initial ILD0 layer or level, it is important to provide low resistance electrodes and low resistance connection between the electrodes and the contacts in the PMD layer, so as to minimize switching times in the resulting memory cells. With respect to the capacitor electrodes, it has been found that conductive metal oxides are preferred for interfacing with the ferroelectric material itself (e.g., in the upper part of the lower electrode, for example), so as to improve switching endurance fatigue properties by curing oxygen vacancies in the ferroelectric material. At the same time, it is desirable to control the crystallinity and orientation of the ferroelectric material that is constructed over the lower electrode, where higher temperature deposition of the ferroelectric material provides better as-deposited material properties. However, conventional ferroelectric cell fabrication techniques do not provide optimum performance due to limitations of the metal oxides used in the capacitor electrode formation, whereby there is a need for improved methods for ferroelectric capacitor and ferroelectric memory cell fabrication by which improved performance and reliability can be achieved.

### SUMMARY OF THE INVENTION

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

The invention relates to semiconductor fabrication techniques in which ferroelectric memory cells and the ferroelectric cell capacitors thereof are created using low temperature metal organic chemical vapor deposition (MOCVD) techniques to deposit the PZT dielectric material of the cell capacitors without significant adverse effect on the metal oxide material of the lower capacitor electrode. The inventors have appreciated that while high PZT deposition temperatures provide better crystallinity in the as-deposited PZT, that such deposition techniques can cause reduction in the oxygen content of metal oxides in the lower capacitor electrode over which the PZT is being deposited, leading to capacitor fatigue and degraded switching endurance. In particular, the inventors have found that Iridium oxide (IrOₓ) is thermodynamically unstable at high pressures and low pressures used in conventional PZT deposition processes, particularly in the slightest of reducing ambients, and that the kinetics of the IrOₓ reduction in such conditions is quite fast. The present invention provides for depositing the PZT at lower temperatures in conditions where the metal oxide is thermodynamically stable, thereby mitigating reduction of the oxide electrode material. In addition to mitigating reduction of the lower electrode oxide material, the low temperature ferroelectric material formation aspects of the invention also facilitate integration of the ferroelectric capacitors in process flows that employ nickel silicide in the transistor level, whereby the benefits of such processes can be realized in devices having PZT based ferroelectric memory cells.

In accordance with one or more aspects of the invention, a method is provided for fabricating a ferroelectric capacitor in a semiconductor device wafer. The method comprises forming a lower electrode, depositing lead zirconate titanate (PZT) ferroelectric material on the lower electrode at a temperature below 450 degrees C. and thereafter forming an upper electrode on the PZT. The PZT deposition temperature may be between 300 and 450 degrees C. in certain implementations, preferably between 400 and 450 degrees C. The lower electrode may include Iridium Oxide (IrOₓ) of any suitable stoichiometry, wherein the lower PZT deposition temperature helps to mitigate reduction in the oxygen content of the IrOₓ, by which the IrOₓ helps to maintain the switching endurance of the resulting ferroelectric capacitor. In one implementation, the IrOₓ and the PZT are deposited ex-situ in different processing chambers, where the wafer may be pre-heated in the PZT deposition chamber in O₂, O₃, N₂O, or other suitable non-reducing ambient so as to stabilize the deposited IrOₓ prior to beginning the PZT deposition. The method may further comprise formation of transistors with silicide structures that comprise nickel silicide or nickel silicide alloys at gate and/or source/drain terminals prior to constructing the capacitors, wherein the low PZT deposition temperatures of the invention mitigate pipe defects and other adverse thermal effects on the silicide structures. In further exemplary implementations, the method may comprise thermal crystallization annealing operations after all or a portion of the upper electrode is formed to facilitate crystallization of the previously deposited PZT material, for example, by rapid thermal annealing (RTA).

In accordance with another aspect of the invention, a method is provided for fabricating a ferroelectric memory cell in a semiconductor device wafer, comprising forming a transistor in the wafer and forming a silicide structure on a gate or source/drain of the transistor, where the silicide structure comprises nickel silicide or an alloy of nickel silicide. A dielectric is then formed over the transistor, and a conductive contact is provided that extends through the dielectric to the silicide structure. The method further comprises forming a lower electrode on at least a portion of the conductive contact, forming PZT ferroelectric material above and in contact with the lower electrode at a temperature below 450 degrees C., forming an upper electrode above and in contact with the PZT, and patterning the upper electrode, the PZT, and the lower electrode to form a patterned ferroelectric capacitor.

Yet another aspect of the invention provides a method of fabricating a ferroelectric memory cell in a semiconductor device wafer. The method comprises forming a transistor in the wafer, forming a silicide structure on the gate or one of the source/drains of the transistor that comprises nickel silicide or an alloy thereof, forming a dielectric over the transistor with a conductive contact extending through the dielectric to the silicide structure, forming a lower electrode on at least a portion of the conductive contact, forming PZT ferroelectric material above and in contact with the lower electrode, forming an upper electrode above and in contact with the PZT, and patterning the upper electrode, the PZT, and the lower electrode to form a patterned vertical ferroelectric capacitor.

Still another aspect of the invention provides a ferroelectric memory cell in a semiconductor device wafer, comprising a transistor formed in the wafer, a silicide structure in contact with a gate or source/drain of the transistor that comprises nickel suicide or an alloy of nickel silicide, a dielectric formed over the transistor, a conductive contact extending through the dielectric to the silicide structure, a lower electrode above and in contact with at least a portion of the conductive contact, a PZT ferroelectric material above and in contact with the lower electrode, and an upper electrode above and in contact with the PZT, where the upper electrode, the PZT, and the lower electrode are patterned to form a patterned vertical ferroelectric capacitor where neither the PZT nor the lower electrode extend above or laterally of any portion of the upper electrode.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1A is a partial side elevation view in section illustrating an exemplary ferroelectric memory cell in a portion of a semiconductor device wafer in accordance with one or more aspects of the invention having a ferroelectric cell capacitor with a lower electrode coupled with a MOS cell transistor source/drain through a PMD layer contact and a nickel silicide structure to form a 1T1C ferroelectric memory cell;

FIG. 1B is a partial side elevation view in section further illustrating the ferroelectric cell capacitor and nickel silicide structure in the memory cell of FIG. 1A;

FIG. 2 is a flow diagram illustrating a semiconductor device fabrication process in accordance with one or more aspects of the invention; and

FIGS. 3A-3P are partial side elevation views in section illustrating formation of a ferroelectric memory cell transistor and ferroelectric capacitor stack in the device of FIGS. 1A and 1B in accordance with one or more aspects of the present invention.

### DETAILED DESCRIPTION OF THE INVENTION

The present invention will now be described with reference to the attached drawing figures, wherein like reference numerals are used to refer to like elements throughout. The invention relates to the use of low deposition temperatures to form PZT ferroelectric material, by which the advantages of stable lower electrode IrOₓ material and nickel silicide structures can be achieved in the fabrication of semiconductor devices. The invention may be carried out in any type of semiconductor device, for example, devices having memory cells with ferroelectric cell capacitors or other devices in which ferroelectric capacitors are used. The various aspects and advantages of the invention are hereinafter illustrated and described in conjunction with the drawings, wherein the illustrated structures are not necessarily drawn to scale.

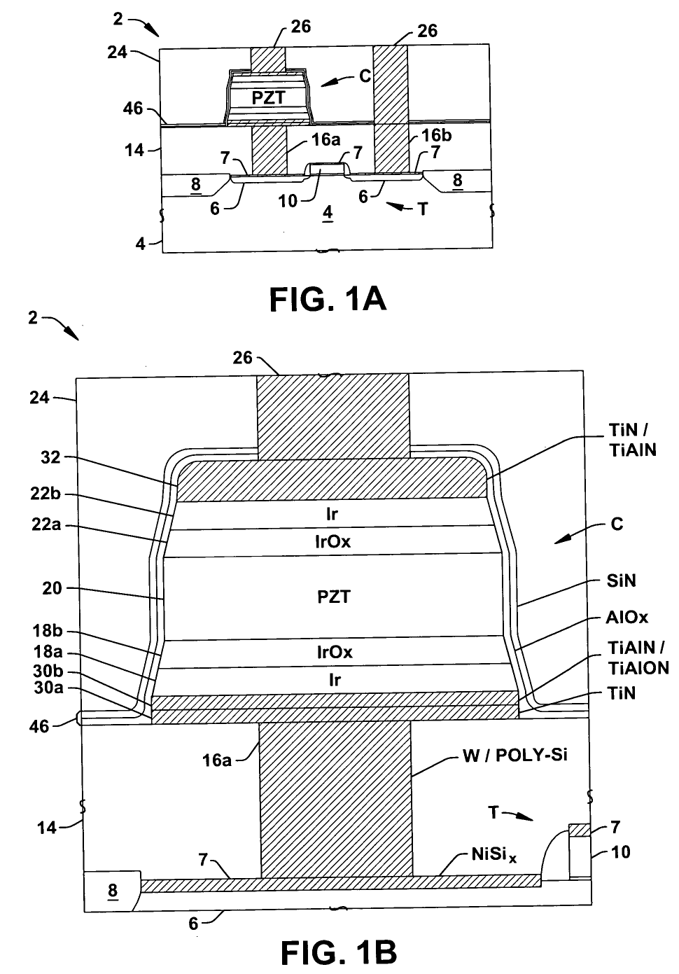

FIGS. 1A and 1B illustrate an exemplary ferroelectric memory cell (1T1C) with a cell transistor T and a ferroelectric capacitor C in a semiconductor device 2 formed in a wafer comprising a silicon substrate 4 in accordance with various aspects of the invention. Although the exemplary device 2 employs 1T1C cell structures, the various aspects of the invention are not limited to any particular cell type, and may alternatively be employed with 2T2C cells or other cell types, wherein all such alternative implementations are contemplated as falling within the scope of the present invention and the appended claims. As illustrated in FIG. 1A, the cell transistor T includes a gate structure 10 having a gate dielectric between a conductive gate electrode and a channel region of the substrate 4, with source/drains 6 formed on either side of the channel in an active region located between STI isolation structures 8. Silicide structures 7 are formed on the transistor source/drains 6 and the gate 10, where the silicide structures 7 comprise nickel silicide (NiSi_{Y}) or nickel silicide alloys (e.g., including nickel and silicon of any suitable stoichiometric ratio, either alone or in combination with cobalt, titanium, tantalum, or other suitable metal or stacks or combinations thereof, collectively referred to hereinafter as nickel silicide).

A pre-metal dielectric (PMD) 14 is provided above the substrate 4 to cover the cell transistor T, where any suitable dielectric material and thickness may be used for the layer 14. A conductive storage node contact 16a and a conductive bitline contact 16b are formed through the PMD layer 14 using any suitable materials and dimensions (e.g., tungsten (W), polysilicon, or other conductive material) to connect with the silicide structures 7 of the cell transistor source/drains 6, wherein the conductive polysilicon electrode of the gate 10 forms a wordline connection in the illustrated device 2. The vertical ferroelectric capacitor C is formed above the cell storage node source/drain contact 16a, including a first or lower electrode 18, 30, with an overlying ferroelectric material (PZT) 20, and a second or upper electrode 22 above the PZT 20. A multilayer sidewall diffusion barrier 46 is formed over the patterned ferroelectric capacitor C, including an aluminum oxide AlO_{X} material and a silicon nitride material SiN. A first inter-level or inter-layer dielectric layer (ILD0) 24 is formed over the barrier 46, and conductive contacts 26 are formed through the dielectric 24 (and through the barrier 46) to couple with the upper capacitor electrode 22 (plateline) and with the bitline contact 16 in the PMD level 14.

As further illustrated in FIG. 1B, the exemplary ferroelectric capacitor C comprises a PZT ferroelectric material 20 sandwiched in a vertical capacitor stack structure between a multilayer upper (top) electrode 22a, 22b (collectively referred to as 22) and a multilayer lower (bottom) electrode 30a, 30b, 18a, 18b (30, 18 collectively), where a remnant portion of a capacitor stack etch hardmask 32 is situated between the upper electrode 22 and an ILD0 plateline contact 26. The lower electrode 30, 18 is formed over at least a portion of the storage node contact 16a in the PMD dielectric 14. Any suitable single or multilayer upper and lower electrodes may be employed within the scope of the invention.

The lower electrode may include a conductive diffusion barrier 30 formed on the storage node contact 16a, for example, depending on whether the PMD contact 16a requires protection during subsequent processing of the capacitor dielectric 20. In such a case, the conductive barrier 30 can be any suitable conductive material that prevents degradation of the contact 16a, such as TiAlN or other possible barriers (some of which have a slow oxidation rate compared to TiN) which include: TaSiN, TiSiN, TiN, TaN, HfN, ZrN, HfAlN, CrN, TaAlN, CrAlN, or any other conductive material, or stacks or combinations thereof, where the barrier 30 is preferably thin, such as having a thickness of about 100 nm or less in one example. The exemplary lower electrode 30, 18 comprises a conductive bilayer diffusion barrier 30a, 30b (collectively 30) formed over the contact 16a for protection thereof during subsequent processing, wherein the exemplary first barrier layer 30a is TiN of any suitable thickness (e.g., about 40 nm in one example), and the second barrier layer 30b is TiAlN of any suitable thickness, such as about 30 nm in the illustrated implementation. Alternatively, the second barrier layer 30b could be TiAlON, or a single barrier layer could be formed over all or a portion of the contact 16a, such as TiAlN having a thickness of about 60 nm in one example.

The other lower electrode layers 18 can be formed either on the barrier 30 or directly on the contact 16a and the PMD dielectric 14 so as to make electrical connection with the underlying contact 16a. Preferably, the lower electrode 18 has a thickness of about 25-100 nm, is stable in oxygen, and is comprised of a noble metal or conductive oxide such as Ir, IrOₓ, Pt, Pd, PdOₓ, Au, Ru, RuOₓ, Rh, RhOₓ, LaSrCoO₃, (Ba,Sr)RuO₃, LaNiO₃ or stacks or combinations thereof. The preferred bottom electrode for a PZT capacitor dielectric is either 50 nm Ir or a stack comprised of 30 nm IrOₓ and 20 nm Ir. In the exemplary device 2, a lower Iridium (Ir) layer 18a is formed on the barrier 30 to any suitable thickness, such as about 20 nm in the illustrated example. A lower Iridium Oxide (IrOₓ) layer 18b is then formed over the lower Ir layer 18a to any suitable thickness, such as about 30 nm in the illustrated implementation. The IrOₓ layer 18b operates to improve switching endurance fatigue properties by curing oxygen vacancies in the overlying PZT material 20, wherein it is desirable to avoid or mitigate reduction of (e.g., loss of oxygen content from) the IrOₓ layer 18b during formation of the PZT 20.

The exemplary ferroelectric material 20 is PZT having any suitable thickness, such as about 300 to 1000 Å, preferably about 700 Å in one example, where the PZT is initially deposited at low temperature in accordance with the invention, so as to avoid or inhibit reduction of the IrOₓ material 18b, wherein the low PZT deposition temperature also helps to avoid pipe defects and other problems associated with the use of nickel silicide structures 7. The PZT 20 may be deposited using metal organic chemical vapor deposition (MOCVD) techniques at temperatures below 450 degrees C. so as to avoid reduction of the IrOₓ layer 18b, and also to mitigate thermal degradation of the nickel silicide structures 7, wherein pulsed or interrupted MOCVD deposition techniques and post-deposition rapid thermal annealing (RTA) may be employed to provide desired material properties of the PZT capacitor dielectric 20, as described in greater detail below.

The upper electrode 22 includes an upper IrOₓ layer 22a formed over the PZT 20 to any suitable thickness, such as about 100 nm or less, as well as an upper Ir layer 22b formed over the upper IrOₓ layer 22a to any suitable thickness, such as about 100 nm or less. A hardmask 32 is formed above the upper Ir layer 22b, for use in patterning the vertical capacitor stack C, where the hardmask 32 can be any suitable material such as TiN, TiAlN, etc. In combination with the PZT ferroelectric material 20, other materials may be substituted for the upper IrOₓ layer 22a, wherein it is advantageous to have a conductive oxide top electrode such as IrOₓ, RuOₓ, RhOₓ, PdOₓ, PtOₓ, AgOₓ, (Ba,Sr)RuO₃, LaSrCoO₃, LaNiO₃, YBa₂Cu₃O₇₋ₓ rather than a single pure noble metal so as to minimize degradation due to many opposite state write/read operations (fatigue). Moreover, it is advantageous to have the upper Ir layer 22b or other suitable noble metal layer above the upper oxide layer 22a to provide low resistance for connection of the upper electrode structure to the plateline contact 26 and the hardmask 32.

A conductive hardmask 32 is formed over the upper electrode 22, and is then patterned and used in selectively etching the upper and lower electrodes and the PZT 20 to define a patterned vertical ferroelectric capacitor structure C as shown in FIG. 1B. The hardmask 32 may be any suitable single or multilayer material and need not remain over the upper electrode following capacitor patterning. In the exemplary device 2, a single layer TiN or TiAlN 32 is formed over the upper Ir layer 22b, and is patterned and used as an etch mask while etching the ferroelectric capacitor C. The device 2 further includes a single or multilayer hydrogen diffusion barrier 46 formed over the patterned capacitor stack structure C, which operates to inhibit hydrogen diffusion into the PZT material 20 during subsequent fabrication processing. In the exemplary device 2, the hydrogen barrier 46 includes an aluminum oxide (AlOₓ) first layer formed over the capacitor C, and a silicon nitride (SiN) second layer formed over the AlOₓ. The ILD0 material 24 is then formed over the barrier 46, and conductive contacts 26 are formed through the ILD0 24 for connection to the upper electrode of the capacitor C (e.g., plateline connection), where the plateline contact 26 may be coupled to the Ir layer 22b through a portion of the remaining hardmask 32, as shown in FIG. 1B, or may be directly connected to the upper Ir 22b.

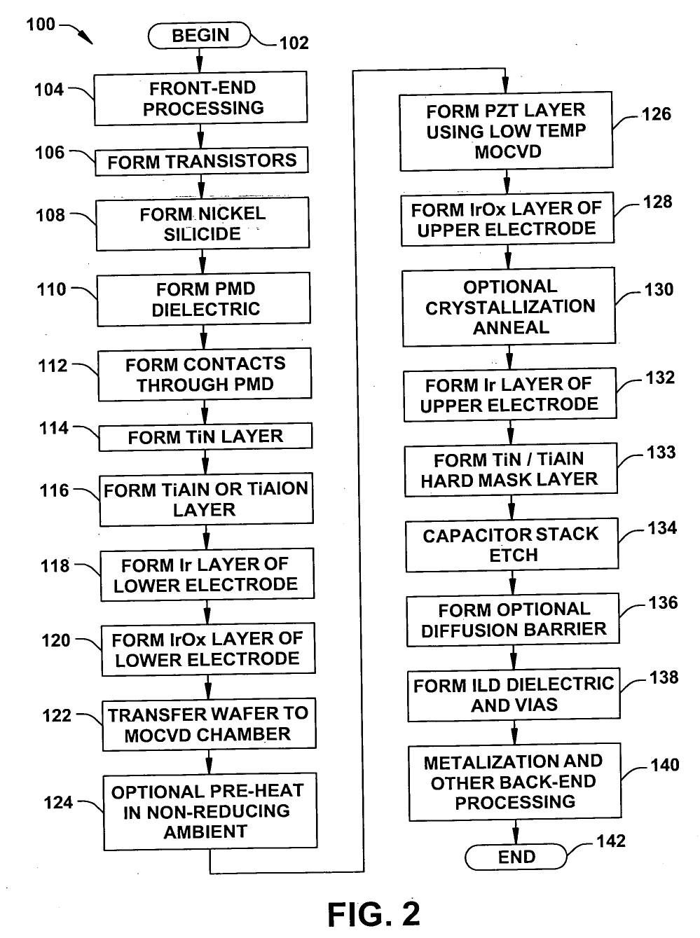

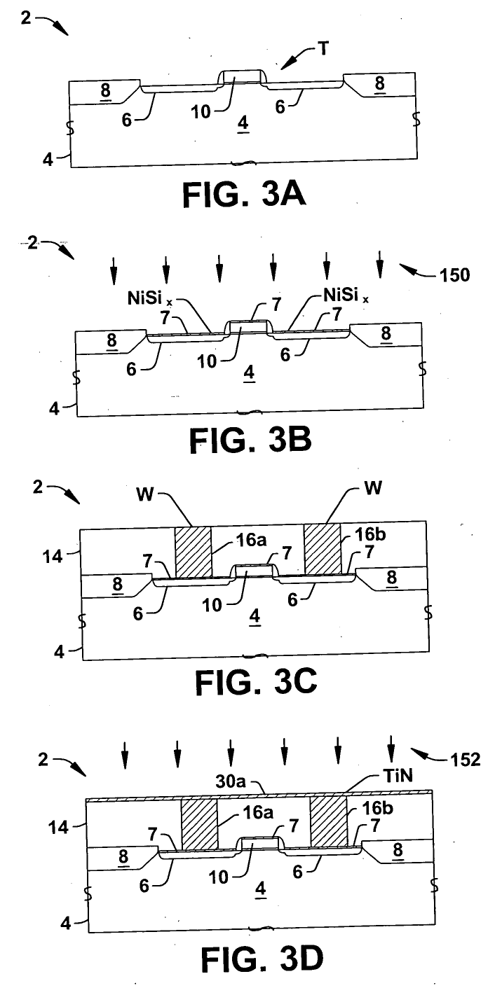

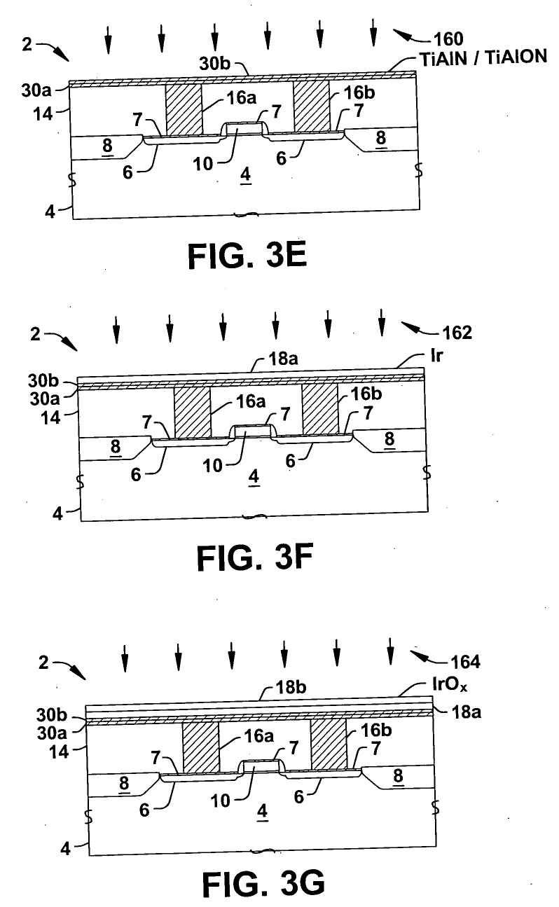

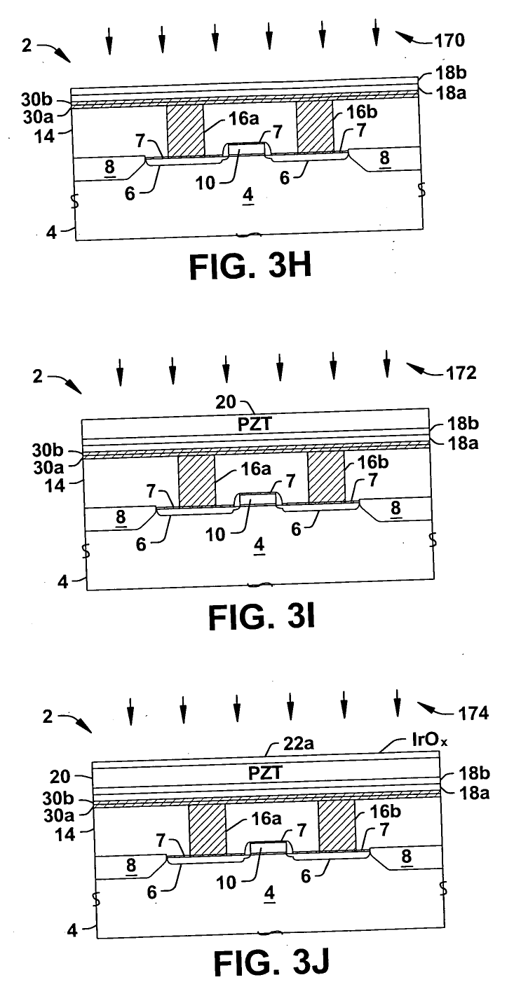

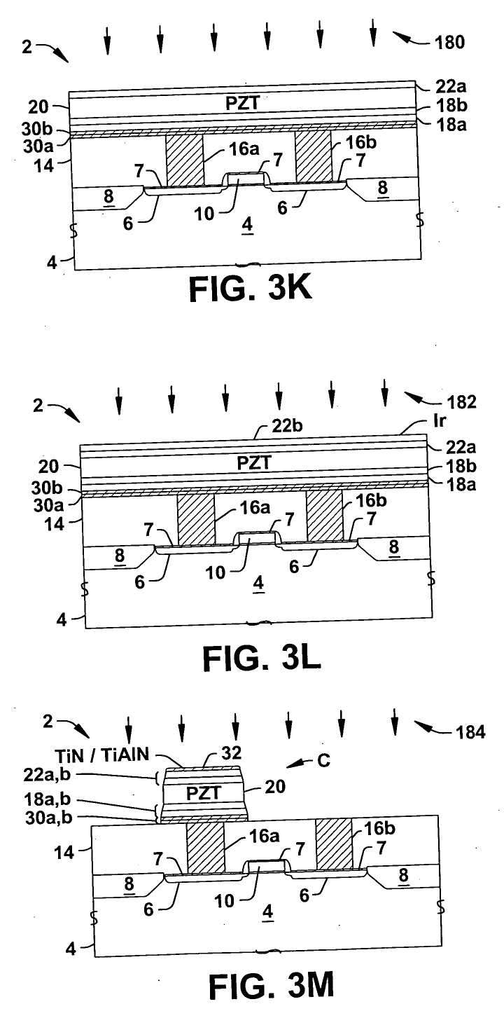

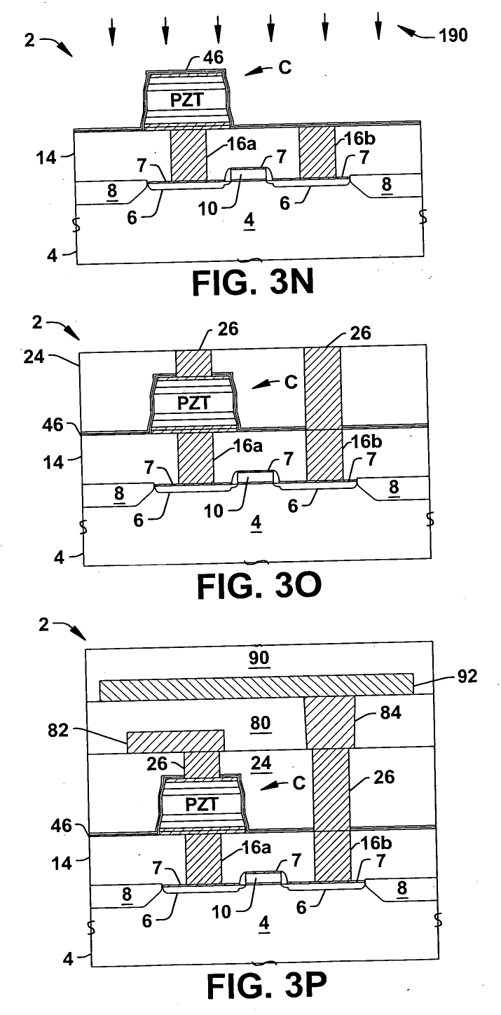

Referring now to FIGS. 2 and 3A-3P, FIG. 2 illustrates an exemplary semiconductor device fabrication process flow or method 100 embodying one or more aspects of the present invention. While the method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. The methods of the present invention, moreover, may be implemented in association with the fabrication of devices illustrated and described herein as well as in association with other devices and structures not illustrated. For example, the exemplary method 100 may be employed in fabricating the exemplary semiconductor device 2 of FIGS. 1A and 1B, as illustrated below in FIGS. 3A-3P. Also, while the following examples illustrate exemplary ferroelectric capacitors formed using PZT ferroelectric materials, Ir/IrOₓ electrode materials, the invention may be employed in association with ferroelectric capacitors fabricated with any suitable electrode materials, wherein all such variant implementations are contemplated as falling within the scope of the present invention.

In addition, while the exemplary semiconductor devices are illustrated herein with ferroelectric capacitors C formed in a dielectric layer or level (ILD0 24 in FIGS. 1A and 1B) after front-end contact formation and prior to formation of overlying metalization levels, various aspects of the invention may be employed at other points in a fabrication process, for example, wherein the ferroelectric capacitors are formed at any level in a multi-level semiconductor device design. Furthermore, the invention may be employed in semiconductor devices (e.g., integrated circuits) fabricated on or in any type of semiconductor body, including but not limited to silicon substrates (e.g., such as the semiconductor body 4 in the device 2 of FIGS. 1A, 1B, and 3A-3P), SOI wafers, epitaxial layers formed above a substrate, etc. In this regard, the invention is not limited to the examples illustrated and described herein, wherein all such alternative implementations are contemplated as falling within the scope of the present invention and the appended claims.

Beginning at 102 in FIG. 2, the method 100 comprises front-end processing at 104, including creating n and p-wells in the semiconductor body 4 and construction of isolation structures (e.g., shallow trench isolation (STI) structures 8 in FIG. 3A or field oxide structures formed using local oxidation of silicon (LOCOS) techniques) in field areas of the wafer. At 106, transistors are formed for logic or analog circuitry and for ferroelectric memory cells (e.g., the exemplary memory cell transistor T is formed in the semiconductor body 4 in FIG. 3A). At 108, silicide structures are formed at the transistor terminals, wherein the silicide structures comprise nickel silicide or alloys of nickel silicide. In FIG. 3B, a silicidation process 150 is performed to create silicide structures 7 on the upper portions of the transistor source/drains 6 and the gate 10. Any suitable silicide formation process 150 may be performed within the scope of the invention at 108. For example, nickel or nickel alloy material may be deposited over the device wafer and an anneal is performed to react the nickel/nickel alloy with the underlying silicon of the source/drains 6 and with the polysilicon of the gate 10, thereby forming the silicide structures 7 comprising nickel silicide or alloys thereof, after which any unreacted materials are removed, leaving the device as shown in FIG. 3B.

At 110, an initial dielectric material is formed over the transistors, referred to herein as a pre-metal dielectric (PMD layer 14 in FIG. 3C), and conductive contacts 16 (e.g., tungsten, polysilicon, or other conductive material) are formed through the PMD layer at 112 for connection to the cell transistor bitline source/drain 6 as well as to the source/drain 6 for connection at a cell storage node with the subsequently formed ferroelectric cell capacitor. In the exemplary device 2, the gate 10 forms a wordline structure, wherein contacts 16 need not be formed directly over the individual transistor gates 10, as illustrated in FIG. 3C. Any suitable dielectric material 14 of any desired thickness can be employed at 110 in forming the initial PMD layer 14. As illustrated in FIG. 3C, tungsten (W) contacts 16a and 16b are formed through the PMD dielectric 14 at 112, coupling with the transistor source/drains 6 via the corresponding nickel silicide structures 7. In one possible implementation, a selective etch process (reactive ion etching or other suitable etch process with appropriate etch mask, not shown) is used at 112 to selectively etch portions of the PMD material 14, thereby creating openings into which tungsten or other conductive material 16 is provided to create the conductive contacts 16a and 16b, as illustrated in FIG. 3C.

At 114-132, ferroelectric capacitor layers are formed over the PMD layer 14 and the contacts 16 thereof (FIGS. 3D-3L), including formation of upper and lower conductive capacitor electrode layers 30, 18, 22, as well as a ferroelectric material (PZT) layer 20 between the electrode layers. In general, any suitable materials, material thicknesses, and layer formation processes may be employed in forming the ferroelectric capacitor material layers within the scope of the invention, except as specifically delineated in the appended claims and as illustrated and described below.

In the illustrated implementation, a conductive diffusion barrier is first created at 114 and 116 comprising a TiN layer 30a formed at 114 over the PMD dielectric 14 and the PMD tungsten contacts 16 (FIG. 3D) to a thickness of about 4 nm via sputtering, chemical vapor deposition (CVD), or other suitable material deposition process 152, although other materials and processes may be employed, including but not limited to TaSiN, TiSiN, TiN, TaN, HfN, ZrN, HfAlN, CrN, TaAlN, CrAlN, or any other conductive material formed to any suitable thickness. In the exemplary method 100, the deposition process 152 used for formation of the TiN layer 30a is reactive sputter deposition using Ar+N₂ or Ar+NH₃, although other inert gases can be substituted instead of Ar for the process 152. Other suitable deposition techniques 152 may include chemical vapor deposition (CVD) or plasma enhanced CVD (PECVD).

Referring also to FIG. 3E, when tungsten (W) is used for the contacts 16, it is preferred to deposit a bilayer diffusion barrier 30a and 30b, as in the exemplary device 2. At 116 in FIG. 2, a TiAlN or TiAlON layer 30b is deposited over the TiN layer 30a via a deposition process 160, as illustrated in FIG. 3E. The layer 30b may be formed to any suitable thickness at 116, such as about 30 nm in the illustrated implementation. Any suitable deposition process 160 may be employed at 160, including but not limited to physical vapor deposition (PVD), CVD or PECVD deposition, wherein a preferred proportion of aluminum in TiAlN is around 30-60% Al, more preferably about 40-50% in order to have improved oxidation resistance.

At 118, a lower electrode metal layer 18a is formed over the barrier 30 via a deposition process 162, as shown in FIG. 3F. In the illustrated example, the layer 18a is Ir deposited by a sputter deposition process 162 to a thickness of about 20 nm at a deposition temperature below 450 degrees C., although CVD or PVD processes and other thicknesses could alternatively be employed at 118. Other suitable conductive materials can be used for the layer 118a, including but not limited to IrOₓ, Pt, Pd, PdOₓ, IrPt alloys, Au, Ru, RuOₓ, (Ba,Sr,Pb)RuO₃, (Sr,Ba,Pb)IrO₃, Rh, RhOₓ, LaSrCoO₃, etc., or any stack or combination thereof. Thereafter at 120, a metal oxide layer 18b is formed, such as IrOₓ deposited using a PVD or sputter deposition process 164 to a thickness of about 30 nm at a temperature below 450 degrees C. in the exemplary device 2, as illustrated in FIG. 3G. In general, the upper and lower electrodes 18 and 22 in the illustrated device 2 are both bi-layers comprising iridium and iridium oxide (Ir and IrOₓ), with lead zirconate titanate (PZT) ferroelectric material 20 formed between the IrOₓ layers of the electrodes, wherein a first layer of Ir 18a and an overlying IrOₓ layer 18b are used with the barrier layers 30a and 30b in the illustrated device 2 to form the lower electrode.

Referring also to FIGS. 3H and 3I, a PZT ferroelectric material 20 is then formed over the lower IrOₓ layer 18b at 126. In accordance with one or more aspects of the invention, the IrOₓ layer 18b is deposited in a first process chamber at 120, while the overlying PZT capacitor dielectric is formed in a different second process chamber at 126, whereby the PZT 20 and the lower IrOₓ layer 18b are formed ex-situ with respect to one another. Accordingly, the device wafer is transferred at 122 to the second chamber (e.g., a metal organic CVD or MOCVD chamber in this example) following the IrOₓ deposition at 120.

Furthermore, the deposited IrOₓ layer 18b is optionally pre-heated in the MOCVD chamber at 124 before beginning PZT deposition, in order to stabilize the IrOₓ 18b. Preferably, a pre-heating operation 170 is performed (FIG. 3H) at 124 in a non-reducing ambient, including but not limited to Oxygen (O₂), Ozone (O₃), nitrous oxide (N₂O), or other suitable non-reducing ambient that prevents or inhibits loss of oxygen from (e.g. reduction of) the IrOₓ material 118b. In one example, the wafer is placed in the MOCVD chamber at 122, Oxygen (O₂) is provided as a gas flow to pressurize the chamber at about 10 Torr or more, and the wafer temperature is elevated to a temperature below 450 degrees C. for a certain time period with no precursor flow, in order to stabilize the IrOₓ phase (e.g., in the IrO₂ phase in one example). In this regard, the IrOₓ material 18b may be any stoichiometric ratio (X value) of Iridium and Oxygen, for example, IrO₂, where X=2, wherein the optional pre-heating at 124 aids in stabilizing the stoichiometry value of X in the material 18b prior to starting the PZT precursor flow.

Referring also to FIG. 3I, the PZT ferroelectric material 20 is deposited at 126 over the lower electrode material 18b using any appropriate deposition process 172, such as metal organic chemical vapor deposition (MOCVD) using any suitable ferroelectric materials, including but not limited to Pb(Zr,Ti)O₃ (lead zirconate titanate, PZT), doped PZT with donors (Nb, La, Ta) acceptors (Mn, Co, Fe, Ni, Al) and/or both, or PZT doped and alloyed with SrTiO₃, BaTiO₃ or CaTiO₃, or stacks or combinations thereof. PZT is the preferable choice for the capacitor dielectric because it has the highest polarization and the lowest processing temperature of the generally available ferroelectric materials, whereby integration into device fabrication processes that use nickel silicide structures 7 is facilitated. In one possible implementation, a preferred Zr/Ti composition is around 20/80, respectively, in order to obtain good ferroelectric switching properties (large switched polarization and relatively square-looking hysteresis loops). Alternatively, Zr/Ti compositions of approximately 65/35 may be preferred to maximize uniformity in capacitor properties. It may be preferred to have donor doped PZT with roughly 0.05 to 1% donor dopant to improve the reliability of the PZT by helping to control the point defect concentrations. The preferred deposition technique for these dielectrics is metal organic chemical vapor deposition (MOCVD), particularly for thin films. Thin PZT is extremely advantageous in making integration simpler (less material to etch), cheaper (less material to deposit therefore less precursor) and allows lower voltage operation (lower coercive voltage for roughly the same coercive electric field).

The capacitor dielectric 20 can be deposited in a generally amorphous phase at low temperatures below 450 degrees C., preferably above about 300 degrees C., more preferably between about 400 and 450 degrees C., wherein the PZT 20 may subsequently be crystallized using a post-deposition anneal, such as the optional anneal described below at 130. During deposition, moreover, the chamber pressure is preferably controlled to about 1 Torr or more, preferably about 1-10 Torr at temperatures between 400 and 450 degrees C., or at a pressure of about 10 Torr or more for deposition temperatures between 300 and 400 degrees C. Where the optional pre-heating was performed at 124 in the PZT deposition chamber, the PZT deposition can be started at 126 simply by starting the flow of the PZT precursors (liquids) into the chamber in the oxidizing (e.g., non-reducing) ambient.

The inventors have appreciated that the low temperature deposition of the PZT material 20 at 126 advantageously prevents or inhibits reduction of the oxygen content of the underlying IrOₓ material 18b, and further facilitates the use of nickel silicide or alloys of nickel silicide for the silicide structures 7. Furthermore, the crystallinity of the deposited PZT 20 can be controlled by the specific MOCVD deposition techniques at 126 and/or may be modified post-deposition, as described below, whereby the invention allows the advantages of low deposition temperature as well as control over the PZT crystallinity and other properties. In this regard, prior techniques involved much higher PZT deposition temperatures (e.g., 650 degrees C. or more in some cases) to control the as-deposited PZT properties, wherein the high PZT deposition temperature has been found to be undesirable for integration with nickel suicides 7 and also causes a reduction in the IrOₓ, resulting in degraded switching endurance fatigue properties of the resulting ferroelectric cell capacitor.

In another aspect of the invention, the PZT deposition process 172 can employ pulsed or interrupted MOCVD deposition, wherein the precursor flow is periodically interrupted (e.g., discontinued and then restarted, while the gas flow is continued) in order to give the deposited atoms a chance to move around during the low temperature deposition at 126. In the MOCVD deposition at 126, the ambient gases are kept flowing (e.g., as in the above-described optional pre-heat at 124), and the PZT deposition starts when liquid precursors, such as hydrocarbon-based hydroxyl compounds of lead, zirconium, and titanium (PZT) are introduced into the chamber pre-mixed in liquid form though a shower head type structure into an oxidizing gas, and the substrate is maintained at less than 450 C. The precursors break down in the oxidizing environment, leading to deposition of the resulting PZT film 20 over the IrOₓ 18b. In one example of such pulsed deposition at 126, the precursors are allowed to flow for about 30 seconds, and are then discontinued for about 60 seconds, and the process is repeated as needed to provide the desired thickness (e.g., 300 to 1000 Å, preferably about 700 Å in the illustrated example).

The inventors have appreciated that the low deposition temperature (e.g., below 450 degrees C.) can thus be used to mitigate reduction of the IrOₓ material 18b, wherein optional pulsed PZT deposition in a separate chamber at 126, the optional pre-heating at 124, and/or the post deposition crystallization annealing at 130 can be employed separately or in combination to help achieve the desired PZT crystallinity and orientation together with the desired lower IrOₓ properties. Further, the low PZT deposition temperature and the optional pulsed form of MOCVD deposition at 126 can help to control the PZT deposition rate and improve the crystallinity without needing the high temperatures that can cause problems with the nickel silicide structures 7, wherein the optional post-deposition annealing at 130 may not be needed.

Referring now to FIGS. 2 and 3J, after the deposition of the PZT material 20, the top electrode is formed at 128-132 using any suitable conductive material or materials, such as Ir, IrOₓ, RuOₓ, RhOₓ, PdOₓ, PtOₓ, AgOₓ, (Ba, Sr)RuO₃, LaSrCoO₃, LaNiO₃, YBa₂Cu₃O₇₋ₓ with a noble metal layer thereover, or stacks or combinations thereof. In the illustrated device 2, the upper electrode is a bi-layer comprising an upper IrOₓ layer 22a formed over the PZT 20, and an Ir layer 22b formed over the IrOₓ layer 22a, wherein the electrode layers may be formed at 128 and 132 to any desired thickness using any suitable processes in accordance with the invention. In the illustrated example, an upper IrOₓ layer 22a is formed at 128 on top of the PZT capacitor dielectric 20 via a sputter deposition process or reactive PVD process 174 in Ar+O₂ (FIG. 3J) to a thickness of about 100 nm or less (e.g., about 30 nm in one example) at a temperature below about 400 degrees C. In particular it is advantageous for Pb based ferroelectrics 20 to have a conductive oxide top electrode such as IrOₓ, RuOₓ, RhOₓ, PdOₓ, PtOₓ, AgOₓ, (Ba,Sr)RuO₃, LaSrCoO₃, LaNiO₃, YBa₂ Cu₃O₇₋ₓ, rather than a pure noble metal directly over the PZT 20 to minimize degradation due to many opposite state write/read operations (fatigue).

Moreover, where the first upper electrode material 22a is an oxide, it is advantageous to have a noble metal layer 22b above it to help maintain low contact resistance between the subsequently formed metal plateline contact 26 and the oxide 22a. Thus, in the exemplary method 100, an upper Ir layer 22b or other suitable metal is deposited at 132. However, an optional crystallization anneal process may be performed at 130 (e.g., thermal process 180 in FIG. 3K) prior to the Ir layer formation at 132 or at any other time following the IrOₓ deposition at 128 to crystallize the deposited PZT 20. In one example, the device wafer is heated to about 450 to 740 degrees C. at 130 for a short time, such as about 10 to 60 seconds, using rapid thermal annealing (RTA) or other suitable technique that provides the desired PZT material properties without violating the time-temperature constraints of the nickel silicide structures 7. At 132, the upper Ir layer 22b is deposited to a thickness of about 100 nm or less over the upper IrOₓ 22a using a deposition process 182, as shown in FIG. 3L. Any suitable deposition process 182, conductive material 22b, and thicknesses can be employed at 132, wherein the exemplary process 182 is a PVD deposition below 400 degrees C. in Ar to form about 20 nm of Ir 22b.

Referring also to FIG. 3M, a hard mask layer 32 is formed (e.g., deposited over the upper Ir layer 22b) at 133 of TiN, TiAlN, or other suitable conductive material, where the hard mask 32 may be a single or multi-layer structure of any suitable thickness. The ferroelectric capacitor layers are patterned at 134 via an etch process 184 at 118, where the hard mask material 32 is pattered according to the desired final size (area) and shape of the capacitor C prior to performing the etch process 184. A portion of the hard mask 32 may remain after completion of the etch process 184 as shown in FIG. 3M, or the hard mask 32 may be removed entirely by the etch 184 or subsequent cleaning operations. Any suitable masking and etching processes 184 may be employed to pattern the upper and lower electrode and PZT layers within the scope of the invention, wherein the etch process 184 may be a single or multi-step process.

Referring also to FIG. 3N, an optional single or multilayer hydrogen diffusion barrier 46 may then be formed at 136 above the patterned ferroelectric capacitor C via suitable deposition process or processes 190 to prevent or inhibit hydrogen diffusion into the ferroelectric material 120 in subsequent (e.g., back-end) processing of the device 2. Preferably, the barrier 46 has a thickness of about 30 nm or less, and comprises a first layer of AlOₓ, Ta₂O₅, AlN, TiO₂, ZrO₂, HfO₂, or any stack or combination thereof, as well as a second barrier layer comprising SiN, AlN, or stacks or combinations thereof with a thickness of about 30 nm or less (e.g., AlOₓ and SiN in the device 2), where the barrier layers 46 can be formed by any suitable processing in accordance with the invention. In the illustrated example, moreover, the AlOₓ layer operates as a lead (Pb) and hydrogen (H) diffusion barrier while the silicon nitride (e.g., Si₃N₄) layer is subsequently used as a contact etch stop. In this example, the AlO_{X} is deposited at 136 over the patterned ferroelectric capacitor stack C using atomic layer deposition (ALD) 190, wherein other deposition techniques and materials may alternatively be used that do not react with the PZT material 20 of the capacitor C. The second hydrogen barrier layer is then formed at 136 by deposition of silicon nitride (Si₃N₄) over the AlO_{X} layer using a PECVD or other suitable deposition process 190.

Following formation of the barrier at 136, an inter-level dielectric (e.g., ILD0) is deposited at 138 (layer 24 in FIG. 30), which is then selectively etched to form via/contact openings for electrical coupling to the upper ferroelectric capacitor electrode 22 and to the previously formed bitline contact 16b in the underlying initial PMD layer 14. The openings are then filled with conductive material (e.g., copper, aluminum, tungsten, or other conductive material) to form the bitline and capacitor plateline contacts or vias 26 in the ILD0 layer (e.g., ILD0 vias (V0) in the capacitor level), as shown in FIG. 30. The ILD material 24 may be silicon dioxide (SiO₂), FSG, or other suitable dielectric. Thereafter, further metalization levels can be formed at 140, as shown in FIG. 3P, including another ILD material 80 (e.g., ILD1 level) with a conductive plateline routing structure 82 and an ILD1 bitline via 84, as well as an overlying ILD2 dielectric 90 in which a conductive (e.g., copper) bitline routing structure 92 is formed, after which other back-end processing is performed (not shown) to complete the device 2.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of fabricating a ferroelectric capacitor in a semiconductor device wafer, the method comprising:
forming a lower electrode;
depositing PZT ferroelectric material on the lower electrode at a temperature below 450 degrees C.; and
forming an upper electrode on the PZT.

2. The method of claim 1, wherein the PZT is deposited at a temperature above 300 degrees C.

3. The method of claim 1, wherein the PZT is deposited at a temperature above 400 degrees C.

4. The method of claim 1, wherein the PZT is deposited using a metal organic chemical vapor deposition process.

5. The method of claim 1, further comprising annealing the wafer after forming at least a portion of the upper electrode to facilitate crystallization of the PZT.

6. The method of claim 1, wherein forming the lower electrode comprises depositing a lower IrOₓ layer, and wherein the PZT is deposited on the lower IrOₓ layer.

7. The method of claim 6, wherein the lower IrOₓ layer is deposited in a first process chamber and the PZT is deposited in a second process chamber.

8. The method of claim 7, further comprising preheating the wafer at a temperature below 450 degrees C. in a non-reducing ambient in the second process chamber after depositing the lower IrOₓ layer and before depositing the PZT.

9. The method of claim 8, wherein the wafer is preheated in O₂, O₃, or N₂O at a temperature below 450 degrees C. in a non-reducing ambient in the second process chamber after depositing the lower IrOₓ layer and before depositing the PZT.

10. The method of claim 6, wherein the lower IrOx layer is deposited at a temperature below 450 degrees C.

11. The method of claim 6, wherein the PZT is deposited using an MOCVD process.

12. The method of claim 1, wherein forming the upper electrode comprises depositing an upper IrOₓ layer on the PZT.

13. The method of claim 12, further comprising annealing the wafer after depositing the upper IrOₓ layer to facilitate crystallization of the PZT.

14. The method of claim 13, wherein the wafer is annealed at a temperature of about 450 degrees C. or more and about 750 degrees C. or less for about 30 seconds or less after depositing the upper IrOₓ layer to facilitate crystallization of the PZT.

15. The method of claim 1, further comprising:
forming a transistor in the wafer before forming the lower electrode;
forming a nickel silicide structure on a gate or source/drain of the transistor before forming the lower electrode; and
forming a conductive contact on the nickel suicide structure before forming the lower electrode;
wherein the lower electrode is formed on the conductive contact.

16. The method of claim 15, wherein forming the lower electrode comprises depositing a lower IrOₓ layer, and wherein the PZT is deposited on the lower IrOₓ layer.

17. The method of claim 16, wherein the lower IrOₓ is deposited in a first process chamber and the PZT is deposited in a second process chamber.

18. The method of claim 17, further comprising preheating the wafer at a temperature below 450 degrees C. in a non-reducing ambient in the second process chamber after depositing the lower IrOₓ layer and before depositing the PZT.

19. The method of claim 15, wherein forming the upper electrode comprises depositing an upper IrOₓ layer on the PZT.

20. The method of claim 19, further comprising annealing the wafer after depositing the upper IrOₓ layer to facilitate crystallization of the PZT.

21. A method of fabricating a ferroelectric memory cell in a semiconductor device wafer, the method comprising:
forming a transistor in the wafer, the transistor having a gate and two source/drains;
forming a silicide structure on the gate or one of the source/drains of the transistor, the silicide structure comprising nickel suicide or an alloy of nickel silicide;
forming a dielectric over the transistor;
forming a conductive contact extending through the dielectric to the silicide structure;
forming a lower electrode on at least a portion of the conductive contact;
forming PZT ferroelectric material above and in contact with the lower electrode at a temperature below 450 degrees C.;
forming an upper electrode above and in contact with the PZT; and
patterning the upper electrode, the PZT, and the lower electrode to form a patterned ferroelectric capacitor.

22. The method of claim 21, wherein the patterned ferroelectric capacitor is a vertical capacitor, with neither the PZT ferroelectric material nor the lower electrode extending above or laterally of any portion of the upper electrode.

23. The method of claim 21, wherein the PZT is formed by metal organic chemical vapor deposition at a temperature above 300 degrees C. and below 450 degrees C.

24. The method of claim 21, further comprising annealing the wafer after forming at least a portion of the upper electrode to facilitate crystallization of the PZT.

25. The method of claim 21, wherein forming the lower electrode comprises:
forming a single or multilayer diffusion barrier above and in contact with at least a portion of the conductive contact;
depositing a lower Ir layer above and in contact with the diffusion barrier; and
depositing a lower IrOₓ layer above and in contact with the lower Ir layer;
wherein the PZT is formed above and in contact with the lower IrOₓ layer.

26. The method of claim 25, wherein the lower IrOₓ layer is deposited in a first process chamber and the PZT is formed in a second process chamber.

27. The method of claim 26, further comprising preheating the wafer at a temperature below 450 degrees C. in a non-reducing ambient in the second process chamber after depositing the lower IrOₓ layer and before forming the PZT.

28. The method of claim 21, wherein forming the upper electrode comprises:
depositing an upper IrOₓ layer above and in contact with the PZT; and
depositing an upper Ir layer above and in contact with the upper IrOₓ layer.

29. The method of claim 28, further comprising annealing the wafer after depositing the upper IrOₓ to facilitate crystallization of the PZT.

30. The method of claim 29, wherein the wafer is annealed at a temperature of about 450 degrees C. or more and about 750 degrees C. or less after depositing the upper IrOₓ layer to facilitate crystallization of the PZT.

31. A method of fabricating a ferroelectric memory cell in a semiconductor device wafer, the method comprising:
forming a transistor in the wafer, the transistor having a gate and two source/drains;
forming a suicide structure on the gate or one of the source/drains of the transistor, the suicide structure comprising nickel silicide or an alloy of nickel silicide;
forming a dielectric over the transistor;
forming a conductive contact extending through the dielectric to the silicide structure;
forming a lower electrode on at least a portion of the conductive contact;
forming PZT ferroelectric material above and in contact with the lower electrode;
forming an upper electrode above and in contact with the PZT; and
patterning the upper electrode, the PZT, and the lower electrode to form a patterned vertical ferroelectric capacitor.

32. A ferroelectric memory cell in a semiconductor device wafer, the ferroelectric memory cell comprising:
a transistor formed in the wafer, the transistor having a gate and two source/drains;
a silicide structure in contact with the gate or on one of the source/drains of the transistor, the silicide structure comprising nickel silicide or an alloy of nickel silicide;
a dielectric formed over the transistor;
a conductive contact extending through the dielectric to the silicide structure;
a lower electrode above and in contact with at least a portion of the conductive contact;
a PZT ferroelectric material above and in contact with the lower electrode; and
an upper electrode above and in contact with the PZT;
wherein the upper electrode, the PZT, and the lower electrode are patterned to form a patterned vertical ferroelectric capacitor, and wherein neither the PZT ferroelectric material nor the lower electrode extend above or laterally of any portion of the upper electrode.
